(19) United States
(12) Patent Application Publication
(10) Pub. No.: US 2021/0062323 A1
(43) Pub. Date: Mar. 4, 2021

(54) VACUUM EVAPORATION SOURCE

(71) Applicant: Alpha Plus Co., Ltd., Asan-si Chungcheongnam-do (KR)

(72) Inventor: Do Weon Hwang, Asan-si Chungcheongnam-do (KR)

(21) Appl. No.: 16/644,236

(22) PCT Filed: Sep. 14, 2017
(86) PCT No.: PCT/KR2017/010096

§ 371 Date: Mar. 4, 2020

(51) Int. Cl. C23C 14/26; C23C 14/24

(52) U.S. Cl. CPC C23C 14/26; C23C 14/243

(57) ABSTRACT

A vacuum evaporation source capable of improving the straightness of a heating wire. To this end, aspects of the present invention provide a vacuum evaporation source including a crucible, including a first heating wire for heating the crucible, and a first upper fixing portion for fixing an upper portion of the first heating wire.

### CROSS REFERENCE TO RELATED APPLICATION

This application is the U.S. National Phase Application of PCT/KR2017/010096, filed Sep. 14, 2017, the contents of such application being incorporated by reference herein.

### TECHNICAL FIELD

The present invention relates to a vacuum evaporation source used to form a thin film on a wafer or substrate.

### BACKGROUND ART

Generally, a vacuum evaporation source heats and evaporates materials for forming a thin film to form a predetermined thin film on a substrate disposed in a high vacuum chamber. It is used to form a thin film made of a specific material on a wafer surface in a semiconductor manufacturing process or to form a thin film of a desired material on a surface of a glass substrate or the like in a manufacturing process of a large flat panel display device.

FIG. 1 is a view schematically showing a conventional vacuum evaporation source.

As shown in FIG. 1, the conventional vacuum evaporation source includes a case 10 having an inner space 11, a crucible 20 provided in the inner space 11 and containing a material for forming a thin film, a heating wire 30 positioned between a side of the inner space 11 and an outer side of the crucible 20 to heat the crucible 20, and a support 40 supporting a bottom of the heating wire 30.

However, the conventional vacuum evaporation source has a problem in that the heating wire 30 is bent by gravity because the support 40 supports the bottom of the heating wire 30. In particular, while the thermal expansion and thermal contraction of the heating wire 30 proceeds a lot, the thermal expansion of the heating wire 30 is repeated in an upward direction and the heating wire 30 is continuously bent under the influence of gravity, thereby ultimately dropping the straightness of the heating wire 30.

### DISCLOSURE OF INVENTION

### Technical Problem

An aspect of the present invention is a vacuum evaporation source capable of improving the straightness of a heating wire.

### Solution of Problem

Aspects of the present invention provide a vacuum evaporation source including a crucible, comprising a first heating wire for heating the crucible, and a first upper fixing portion for fixing an upper portion of the first heating wire.

The first heating wire may include a first upward bent portion that is bent in an upwardly convex shape. The first upper fixing portion may include a bent lower fixing member for supporting a lower portion of the first upward bent portion, and a bent upper fixing member for supporting an upper portion of the first upward bent portion.

The first heating wire may further include a second upward bent portion that is bent in an upwardly convex shape at an interval with the first upward bent portion. The bent lower fixing member may have a ring shape surrounding the crucible to support each lower portion of the first and second upward bent portions together. The bent upper fixing member may have a ring shape surrounding the crucible to support each upper portion of the first and second upward bent portions together.

The vacuum evaporation source according to an embodiment of the present invention described above may further include a case with an inner space to accommodate the crucible, and a reflective plate provided between a side of the inner space and the first heating wire, in which each of the bent lower fixing member and the bent upper fixing member may be supported by the reflective plate.

The first heating wire may include a first downward straight portion and a second downward straight portion extending in a downward direction on both sides of the first upward bent portion, respectively, in which the first and second downward straight portions may penetrate the bent lower fixing member.

Each of the bent lower fixing member and the bent upper fixing member may be made of an insulating material.

The vacuum evaporation source according to an embodiment of the present invention described above may further include a second heating wire for heating the crucible, and a second upper fixing portion for fixing an upper portion of the second heating wire, in which the first heating wire may be positioned to correspond to an upper half of the crucible, and the second heating wire may be positioned to correspond to a lower half of the crucible.

### Advantageous Effects

As described above, the vacuum evaporation source according to the embodiment of the present invention may have the following effects.

According to the embodiment of the present invention, it provides a technical configuration including a first heating wire and a first upper fixing portion. Therefore, since the first heating wire is suspended in a downward direction by the first upper fixing portion, the straightness of the first heating wire may be improved by the influence of gravity. In particular, the first heating wire has a suspending shape while being blocked from being thermally expanded upward by the first upper fixing portion. Therefore, as the thermal expansion and thermal contraction of the first heating wire proceeds a lot, the deformation occurs only in the downward direction, which is the direction of gravity, so that the straightness of the first heating wire may be further improved by the influence of gravity.

### BRIEF DESCRIPTION OF THE DRAWINGS

FIG. 1 is a view schematically showing a conventional vacuum evaporation source.

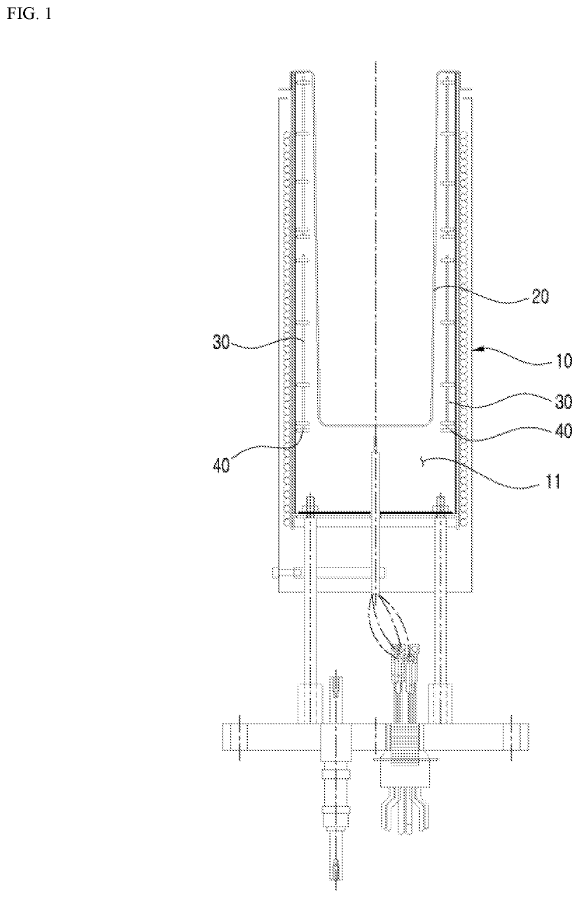

FIG. 2 is a view schematically showing a vacuum evaporation source according to an embodiment of the present invention.

FIG. 3 is an exploded view of first and second heating wires and first and second upper fixing portions of the vacuum evaporation source of FIG. 2.

FIG. 4 is a perspective view schematically illustrating a state in which the first heating wire is fixed to the first upper fixing portion.

FIG. 5 is a view illustrating a comparison between before (a) and after (b) the thermal expansion of the first and second heating wires in FIG. 3.

### MODE FOR THE INVENTION

Hereinafter, embodiments of the present invention will be described in detail with reference to the accompanying drawings so that those skilled in the art may easily implement aspects of the present invention. However, aspects of the invention may be implemented in many different forms, and it is not limited to embodiments described herein.

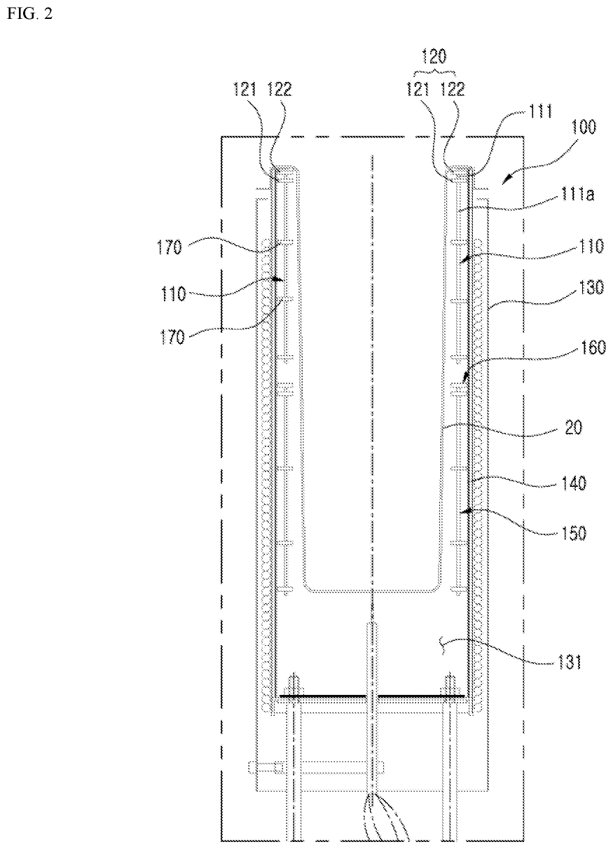

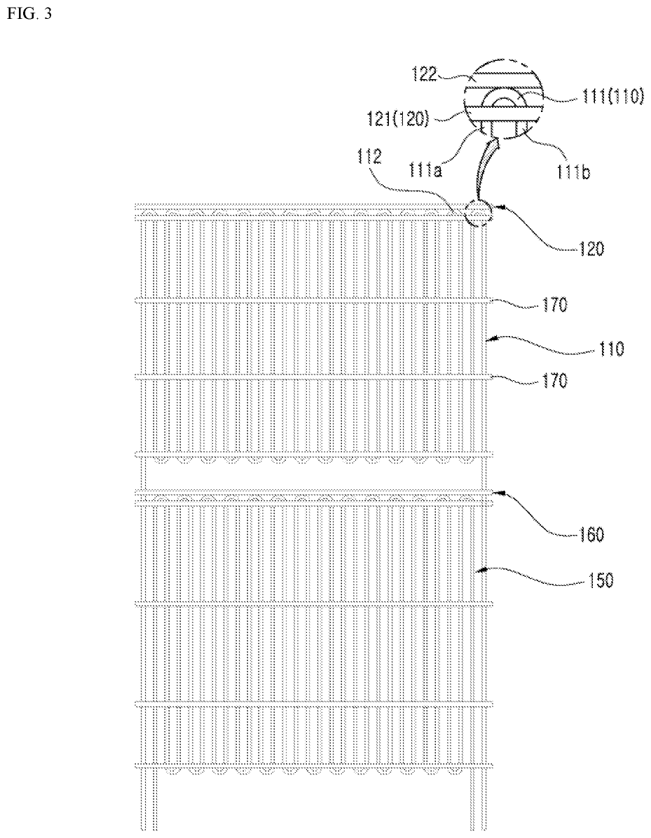

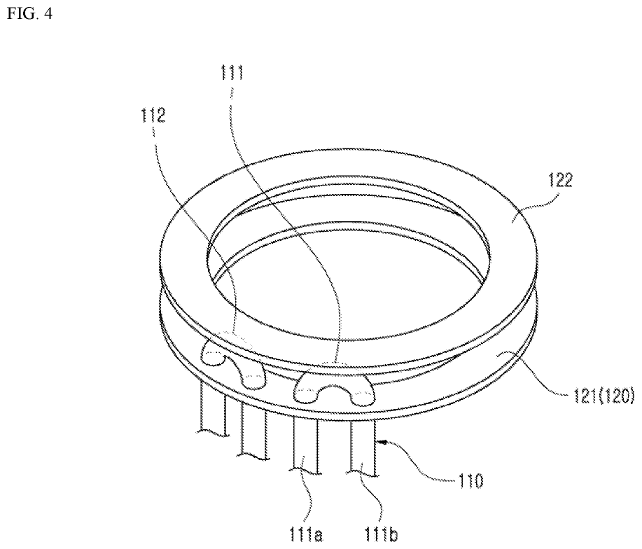

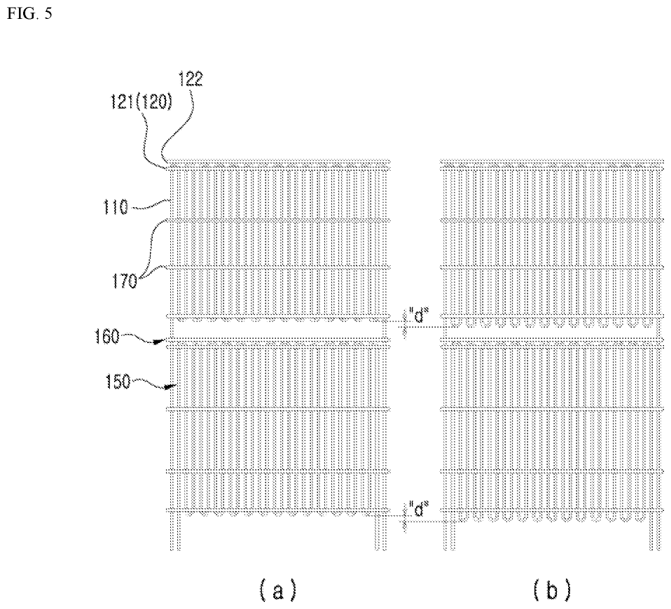

FIG. 2 is a view schematically showing a vacuum evaporation source according to an embodiment of the present invention. FIG. 3 is an exploded view of first and second heating wires and first and second upper fixing portions of the vacuum evaporation source of FIG. 2. FIG. 4 is a perspective view schematically illustrating a state in which the first heating wire is fixed to the first upper fixing portion. FIG. 5 is a view illustrating a comparison between before (a) and after (b) the thermal expansion of the first and second heating wires in FIG. 3.

As shown in FIGS. 2 to 5, a vacuum evaporation source 100 including a crucible 20 according to an embodiment of the present invention includes a first heating wire 110 and a first upper fixing portion 120. Hereinafter, each component will be described in detail with continued reference to FIGS. 2 to 5.

The first heating wire 110 is a component for heating the crucible 20, and as shown in FIG. 2, the first heating wire 110 may be positioned at an upper half of the crucible 20 to heat the upper half of the crucible 20.

Specifically, the first heating wire 110 may include a first upward bent portion 111 that is bent in an upwardly convex shape as shown in FIGS. 3 and 4. In addition, as shown in FIGS. 3 and 4, the first heating wire may 110 further include a second upward bent portion 112 that is bent in an upwardly convex shape at an interval with the first upward bent portion 111. Naturally, depending on a size of the crucible 20, as shown in FIG. 3, the first heating wire 110 may be bent several times, and the number of upward bent portions may be determined by the number of bending.

As shown in FIGS. 2 to 4, the first upper fixing portion 120 is a component for fixing an upper portion of the first heating wire 110. Therefore, since the first heating wire 110 is suspended in a downward direction by the first upper fixing portion 120, the straightness of the first heating wire 110 may be improved by the influence of gravity.

For example, the first upper fixing portion 120 may include a bent lower fixing member 121 and a bent upper fixing member 122 as shown in FIGS. 2 to 4. The bent lower fixing member 121 serves to support a lower portion of the first upward bent portion 111 of the first heating wire 110, and the bent upper fixing member 122 serves to support an upper portion of the first upward bent portion 111 of the first heating wire 110. Accordingly, the first heating wire 110 is blocked from being thermally expanded upward by the bent upper fixing member 122 and has a form suspended from the bent lower fixing member 121. Therefore, as the thermal expansion and thermal contraction of the first heating wire 110 proceeds a lot, the deformation occurs only in a downward direction, which is a direction of gravity, so that the straightness of the first heating wire 110 may be further improved by the influence of gravity.

Furthermore, as shown in FIG. 4, the bent lower fixing member 121 has a ring shape surrounding the crucible 20 to support each lower portion of the first and second upward bent portions 111 and 112 together. The bent upper fixing member 122 may also have a ring shape surrounding the crucible 20 to support each upper portion of the first and second upward bent portions 111 and 112 together. Therefore, each lower portion of a plurality of upwardly bent portions (see 111 and 112) may be simultaneously supported by one bent lower fixing member 121, and each upper portion of the plurality of upwardly bent portions (see 111 and 112) may be simultaneously supported by one bent upper fixing member 122. Thus, the configuration may be simplified, and the cost of parts may be reduced.

In addition, in order to prevent the short circuit of the first heating wire 110 in advance, each of the bent lower fixing member 121 and the bent upper fixing member 122 may be made of an insulating material such as ceramic.

Furthermore, as shown in FIG. 4, the first heating wire 110 may include a first downward straight portion 111a and a second downward straight portion 111b that extend downwardly on both sides of the first upward bent portion 111, respectively, in which the first and second downward straight portions 111a and 111b may penetrate the bent lower fixing member 121 to be movable upward and downward. Therefore, even if the first and second downward straight portions 111a and 111b are thermally expanded and thermally contracted, a length of the first and second downward straight portions 111a and 111b is not prevented from extending or shrinking.

In addition, the vacuum evaporation source 100 according to the embodiment of the present invention described above may further include a case 130 and a reflective plate 140, as shown in FIG. 2. The case 130 has an inner space 131 for accommodating the crucible 20, and the reflective plate 140 is provided between a side of the inner space 131 and the first heating wire 110 to reflect the heat of the first heating wire 110 to the crucible 20.

As such, when the case 130 and the reflective plate 140 are further included, each of the bent lower fixing member 121 and the bent upper fixing member 122 as described above may be supported by the reflective plate 140, as shown in FIG. 2.

Furthermore, a guide member 170 may be further provided to guide the vertical movement of the first heating wire 110 freely and limit the horizontal movement.

In addition, the vacuum evaporation source 100 according to the above-described embodiment of the present invention may further include a second heating wire 150 and a second upper fixing portion 160, as shown in FIGS. 2 and 3.

The second heating wire 150 is a component for heating the crucible 20, and as shown in FIG. 2, the second heating wire 150 may be positioned at a lower half of the crucible 20 to heat the lower half of the crucible 20. In addition, since the second heating wire 150 has the same configuration as the first heating wire 110 described above other than the provided position thereof, specific configurations and actions/effects thereof are as described above.

As shown in FIGS. 2 and 3, the second upper fixing portion 160 is a component for fixing an upper portion of the second heating wire 150. Therefore, since the second heating wire 150 is suspended in the downward direction by the second upper fixing portion 160, the straightness of the second heating wire 150 may be improved by the influence of gravity. In addition, since the second upper fixing portion 160 has the same configuration as the first upper fixing portion 120 described above other than the provided position thereof, specific configurations and actions/effects thereof are as described above.

Hereinafter, with reference to FIG. 5, a state before (a) and after (b) of heating of the first and second heating wire 110 and 150 is described.

When the first and second heating wires 110 and 150 are heated and cooled, the first and second heating wires 110 and 150 are extended and shrunk by “d” as shown in FIG. 5. In particular, a reference fixing point at which the first heating wire 110 extends is the first upper fixing portion 120, and a reference fixing point at which the second heating wire 150 extends is the second upper fixing portion 160, so that the position always remains constant.

In particular, the stability of the form in which the first heating wire 110 should be maintained in the same shape while the first heating wire 110 is thermally expanded and contracted by high temperature heating and cooling is important. To this end, it provides a technical configuration capable of fixing the upper portion of the first heating wire 110 so that, in the case of thermal expansion and thermal contraction of the first heating wire 110, the first heating wire 110 may be suspended below the first upper fixing portion 120 and may be repeatedly extended and shrunk in the same shape in the downward direction by gravity. As a result of experiments, by setting a position where the upper portion of the first heating wire 110 is fixed to the first upper fixing portion 120 and is always a reference position during expansion and contraction to the top, a more stable structure has been realized in the thermodynamic shape change of the first heating wire 110 depending on the number of times and time of use. In addition, since the first heating wire 110 is suspended in the downward direction, which is the direction of gravity, as the thermal expansion and thermal contraction proceeds a lot, the straightness of the first heating wire 110 is improved. Therefore, it was possible that the possibility that the first heating wires 110 collide with each other was significantly reduced. Naturally, the same experimental result was also obtained for the second heating wire 150. Although the preferred embodiment of the present invention has been described in detail above, the scope of the present invention is not limited thereto. Various modifications and improvements of those skilled in the art using the basic concept of aspects of the present invention as defined in the following claims are also within the scope of the present invention.

### INDUSTRIAL APPLICABILITY

Since aspects of the present invention relate to a vacuum evaporation source, they may be applied to manufacturing semiconductors or the like and thus have industrial applicability.

1. A vacuum evaporation source including a crucible, comprising:
a first heating wire for heating the crucible; and
a first upper fixing portion for fixing an upper portion of the first heating wire.

2. The vacuum evaporation source of claim 1, wherein the first heating wire comprises a first upward bent portion that is bent in an upwardly convex shape, and
wherein the first upper fixing portion comprises:
a bent lower fixing member for supporting a lower portion of the first upward bent portion; and
a bent upper fixing member for supporting an upper portion of the first upward bent portion.

3. The vacuum evaporation source of claim 2, wherein the first heating wire further comprises a second upward bent portion that is bent in an upwardly convex shape at an interval with the first upward bent portion,
wherein the bent lower fixing member has a ring shape surrounding the crucible to support each lower portion of the first and second upward bent portions together, and
wherein the bent upper fixing member has a ring shape surrounding the crucible to support each upper portion of the first and second upward bent portions together.

4. The vacuum evaporation source of claim 2, wherein the vacuum evaporation source further comprises:
a case with an inner space to accommodate the crucible, and
a reflective plate provided between a side of the inner space and the first heating wire, and
wherein each of the bent lower fixing member and the bent upper fixing member is supported by the reflective plate.

5. The vacuum evaporation source of claim 2, wherein the first heating wire comprises a first downward straight portion and a second downward straight portion extending in a downward direction on both sides of the first upward bent portion, respectively, and
wherein the first and second downward straight portions penetrate the bent lower fixing member.

6. The vacuum evaporation source of claim 2, wherein each of the bent lower fixing member and the bent upper fixing member is made of an insulating material.

7. The vacuum evaporation source of claim 1, wherein the vacuum evaporation source further comprises:
a second heating wire for heating the crucible, and
a second upper fixing portion for fixing an upper portion of the second heating wire, and
wherein the first heating wire is positioned to correspond to an upper half of the crucible, and
wherein the second heating wire is positioned to correspond to a lower half of the crucible.
